(19) United States
(12) Patent Application Publication
(10) Pub. No.: US 2021/0276054 A1
(43) Pub. Date: Sep. 9, 2021

(54) OIL REMOVAL METHOD, BONDING METHOD, ASSEMBLY DEVICE, AND ATMOSPHERIC-PRESSURE PLASMA DEVICE

(71) Applicant: FUJI CORPORATION, Chiryu (JP)

(72) Inventors: Takahiro JINDO, Anjo-shi (JP); Takuya IWATA, Konan-shi (JP); Akihiro NIWA, Anjo-shi (JP); Akihiro HIGASHIDA, Chiryu-shi (JP)

(73) Assignee: FUJI CORPORATION, Chiryu (JP)

(21) Appl. No.: 17/258,233

(22) PCT Filed: Aug. 2, 2018
(86) PCT No.: PCT/JP2018/028988

§ 371 Date: Jan. 6, 2021

(51) Int. Cl. B08B 7/00; H01J 37/32

(52) U.S. Cl. CPC B08B 7/0035; H01J 37/32522; B08B 2220/00; H01J 37/32532; H01J 2237/335; H01J 37/32449

(57) ABSTRACT

An object of the present invention is to provide a technique capable of removing oil regardless of a shape of a target object to which the oil is attached. Cutting oil is decomposed by irradiating the cutting oil with a plasma gas containing oxygen plasma. Oxygen radicals decompose a carbon element and a hydrogen element constituting the oil into carbon dioxide and water, respectively, to remove the oil. Therefore, paraffin and ester contained in the cutting oil can be decomposed by irradiating the cutting oil with the plasma gas containing oxygen plasma. Since the plasma gas can flow along a shape of a target object, the oil can be removed regardless of a shape of a portion of the target object to which the oil is attached.

### TECHNICAL FIELD

The present application relates to an oil removal method, a bonding method, an assembly device, and an atmospheric-pressure plasma device.

### BACKGROUND ART

In recent years, various studies have been made on the use of plasma, and, for example, Patent Literature 1 discloses an antioxidant treatment method for an oily component-containing substance using water vapor plasma.

### PATENT LITERATURE

Patent Literature 1: JP-A-2010-246509

### BRIEF SUMMARY

### Technical Problem

There are many opportunities for oil to be used in the manufacturing process or the use process of industrial products. There are also many concomitant opportunities for oil removal to be required. For example, in the automobile manufacturing process, when the cutting of a metal serving as a component is performed, cutting oil is used. The cutting oil generally reduces the adhesiveness in bonding using a bonding agent, and is thus required to be removed prior to bonding of molded components. However, a cutting surface of the metal is often uneven, and thus the cutting oil may not be completely removed even though the cutting oil is wiped.

The present application has been proposed in light of the above problem, and an object thereof is to provide a technique capable of removing oil regardless of a shape of a target object to which the oil is attached.

### Solution to Problem

The present specification discloses an oil removal method including a step of irradiating oil attached to a target object with a plasma gas that has been plasmatized by atmospheric-pressure plasma.

The present specification discloses a bonding method including an oil removal step of removing the oil attached to the target object by using the oil removal method; and a bonding step of bonding the target object to an object to be bonded by interposing a bonding agent between a portion of the target object from which the oil has been removed and the object to be bonded.

The present specification discloses an assembly device including an irradiation section configured to irradiate oil attached to a target object made of a resin with a plasma gas containing oxygen plasma that has been plasmatized by atmospheric-pressure plasma; a control section configured to control a temperature of the plasma gas to be a temperature lower than a melting point of the target object; and a bonding section configured to bond the target object to an object to be bonded by interposing a bonding agent between a portion of the target object from which the oil has been removed and the object to be bonded.

The present specification discloses an atmospheric-pressure plasma device including an irradiation section configured to irradiate oil attached to a target object made of a resin with a plasma gas containing oxygen plasma that has been plasmatized by atmospheric-pressure plasma; and a control section configured to control a temperature of the plasma gas to be a temperature lower than a melting point of the target object, wherein the irradiation section has: a pair of electrodes configured to generate plasma through discharge, a reaction chamber that incorporates the pair of electrodes and includes an outlet through which the plasma gas plasmatized by the pair of electrodes flows out, a nozzle block that communicates with the reaction chamber, the nozzle block being configured to eject the plasma gas, a cooler that has a gas flow path through which a cooling-heating gas flows, the cooler being configured to cool the reaction chamber, and a gas pipe that is connected to the gas flow path and through which the cooling-heating gas flows, a heating device that is disposed at the gas pipe, and

a connecting section that is connected to the gas pipe and has an ejection port in a flow path for the plasma gas, wherein the cooling-heating gas heated by the heating device is ejected to the plasma gas from the ejection port so that the plasma gas is heated, and wherein the control section controls a temperature of the plasma gas by controlling the heating device.

### Advantageous Effects

According to the present disclosure, it is possible to provide a technique capable of removing oil regardless of a shape of a target object to which oil is attached.

### BRIEF DESCRIPTION OF DRAWINGS

FIG. 1 is a perspective view illustrating an atmospheric-pressure plasma device.

FIG. 2 is a sectional view illustrating a plasma gas ejection device and a heating gas supply device.

FIG. 3 is a block diagram illustrating a control system of the atmospheric-pressure plasma device.

FIG. 4 illustrates FTIR spectra results before and after irradiation with a plasma gas, in which FIG. 4(a) illustrates the oil-level concentration of 15%, FIG. 4(b) illustrates the oil-level concentration of 10%, FIG. 4(c) illustrates the oil-level concentration of 5%, and FIG. 4(d) illustrates the oil-level concentration of 0%.

FIG. 5 is a schematic diagram for explaining decomposition of cutting oil using plasma gas irradiation.

FIG. 6 illustrates results of tensile shear stress before and after plasma treatment at each oil-level concentration.

FIG. 7 is a diagram illustrating an assembly device.

### DESCRIPTION OF EMBODIMENTS

### First Embodiment

### (Atmospheric-Pressure Plasma Device)

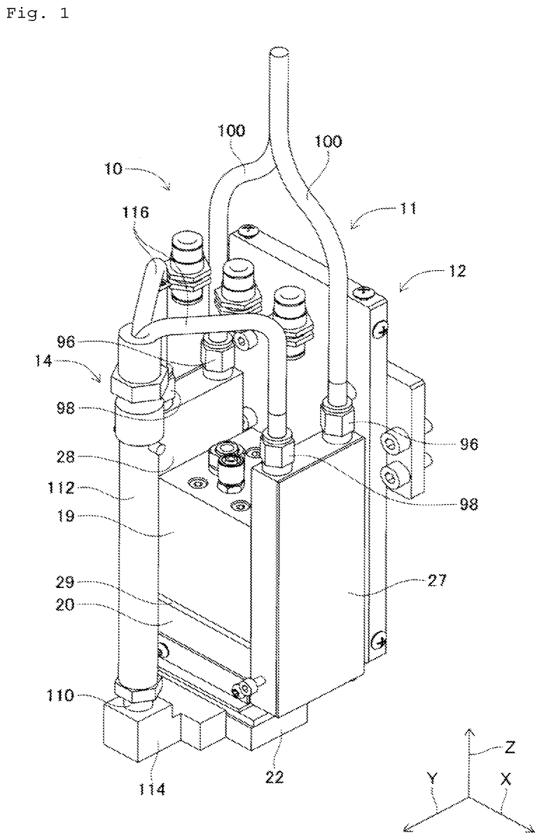

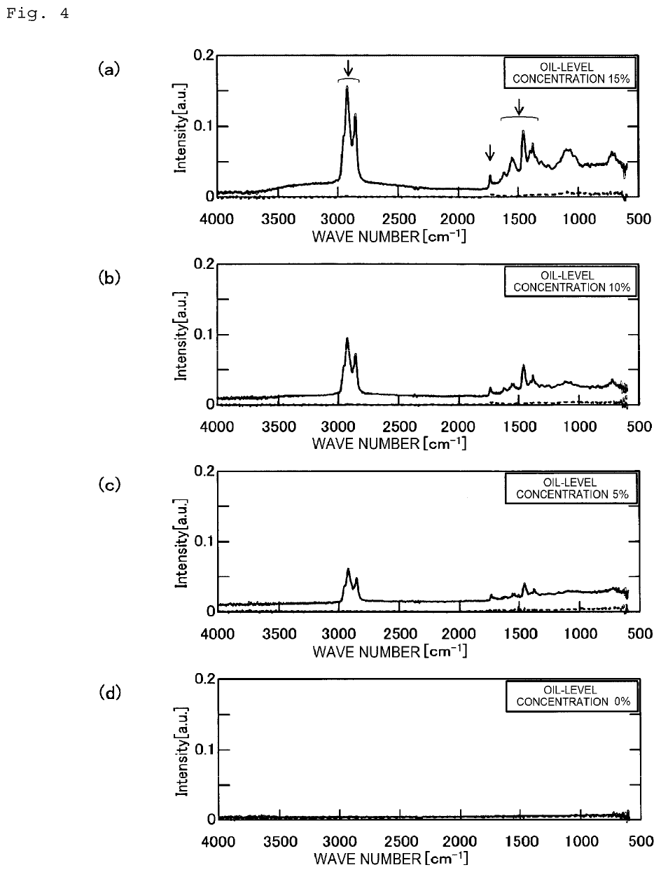

As illustrated in FIG. 1, atmospheric-pressure plasma device 10 includes plasma head 11 covered with a protection cover (not illustrated), and control device 16 (FIG. 3). Plasma head 11 includes plasma gas ejection device 12 and heating gas supply device 14. In the following description, a width direction of plasma head 11 is set to an X direction, a depth direction of plasma head 11 is set to a Y direction, and a direction perpendicular to the X direction and the Y direction, that is, a vertical direction is set to a Z direction.

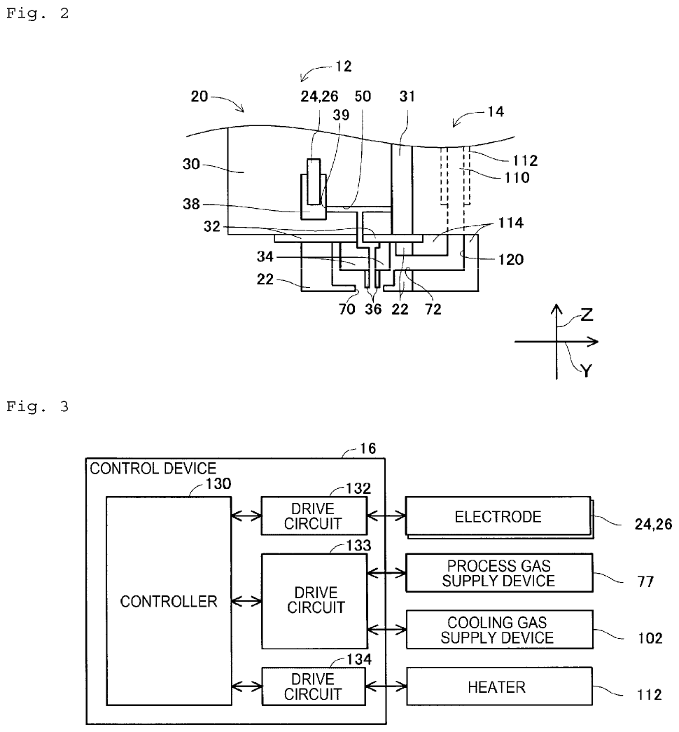

Plasma gas ejection device 12 includes upper housing 19, lower housing 20, lower cover 22, a pair of electrodes 24 and 26 (FIG. 2), and a pair of heat sinks 27 and 28. Upper housing 19 and lower housing 20 are connected to each other via rubber seal member 29 in a state in which upper housing 19 is disposed on lower housing 20. Upper housing 19 and lower housing 20 in a state of being connected are sandwiched by the pair of heat sinks 27 and 28 on both side surfaces thereof in the X direction.

As will be described later, a plasma gas is generated in reaction chamber 38 formed inside lower housing 20, and the generated plasma gas is ejected downward from a lower surface of lower cover 22. Heat sinks 27 and 28 have a function of cooling upper housing 19 and lower housing 20 and the like. A flow path extending from supply port 96 to exhaust port 98 is formed inside each of heat sinks 27 and 28. Supply port 96 is supplied with a cooling gas that is air with about room temperature from cooling gas supply device 102 via supply pipe 100 (FIG. 3). The cooling gas is warmed through heat exchange and is exhausted from exhaust port 98.

Heating gas supply device 14 includes gas pipe 110, heater 112, and connecting block 114. Gas pipe 110 is connected to the flow path through which the cooling gas flows, formed inside heat sinks 27 and 28. Specifically, gas pipe 110 is connected to exhaust ports 98 of the pair of heat sinks 27 and 28 at the upper end via discharge pipe 116. Discharge pipe 116 is bifurcated at a first end, and the bifurcated ends are connected to exhaust ports 98 of the pair of heat sinks 27 and 28. On the other hand, a second end of the discharge pipe 116 is not branched, and is connected to an upper end of gas pipe 110. Consequently, a gas discharged from the pair of heat sinks 27 and 28 is supplied to gas pipe 110. Generally, cylindrical heater 112 is disposed on an outer circumferential surface of gas pipe 110, and gas pipe 110 is heated by heater 112. Consequently, the gas supplied from heat sinks 27 and 28 to gas pipe 110 is heated.

Next, with reference to FIG. 2, an internal structure of plasma gas ejection device 12. Lower housing 20 includes main housing 30, heat radiation plate 31, earth plate 32, connecting block 34, and nozzle block 36. Main housing 30 generally has a block shape, and reaction chamber 38 is formed inside main housing 30. Reaction chamber 38 has an inlet (not illustrated) through which a process gas flows thereinto and outlet 39 through which a plasma gas flows out.

Earth plate 32 functions as a lightning rod and is fixed to a lower surface of main housing 30. Connecting block 34 is fixed to a lower surface of earth plate 32, and nozzle block 36 is fixed to a lower surface of connecting block 34. Heat radiation plate 31 is disposed on a side surface of main housing 30. Heat radiation plate 31 has multiple fins (not illustrated) to radiate heat of main housing 30. Gas flow path 50 is formed in main housing 30, earth plate 32, connecting block 34, and nozzle block 36. That is, nozzle block 36 communicates with reaction chamber 38.

Connecting block 114 is connected to a lower end of gas pipe 110 and is also fixed to a side surface of lower cover 22 on heating gas supply device 14 side in the Y direction. Communication path 120 is formed in connecting block 114, and a first end of communication path 120 is open to an upper surface of connecting block 114 and a second end of communication path 120 is open to a side surface thereof on plasma gas ejection device 12 side in the Y direction. The first end of communication path 120 communicates with the lower end of gas pipe 110, and the second end of communication path 120 communicates with through-hole 72 of lower cover 22. Consequently, a gas heated in gas pipe 110 is supplied to lower cover 22.

The pair of electrodes 24 and 26 are disposed to face each other inside reaction chamber 38 of main housing 30. Reaction chamber 38 is supplied with a process gas obtained by mixing an active gas such as oxygen and an inert gas such as nitrogen at any ratio from process gas supply device 77 (FIG. 3) via a gas supply path (not illustrated)

As illustrated in FIG. 3, in the control system of atmospheric-pressure plasma device 10, control device 16 is communicatively connected to process gas supply device 77 and cooling gas supply device 102, and each constituent is controlled by control device 16. Control device 16 includes computer-based controller 130 and drive circuits 132 to 134. Drive circuit 132 is a circuit controlling power supplied to electrodes 24 and 26. Drive circuit 133 is a circuit controlling a flow rate of each gas supplied by process gas supply device 77 and cooling gas supply device 102. Drive circuit 134 is a circuit controlling power supplied to heater 112.

In atmospheric-pressure plasma device 10, in plasma gas ejection device 12, a process gas is plasmatized in reaction chamber 38 by the above-described configuration, and a plasma gas is ejected from the lower end of nozzle block 36. Specifically, the process gas is supplied to the inside of reaction chamber 38 by process gas supply device 77. In this case, in reaction chamber 38, a voltage is applied to the pair of electrodes 24 and 26 built into reaction chamber 38, and a current flows between the pair of electrodes 24 and 26. Consequently, discharging occurs between the pair of electrodes 24 and 26, the process gas is plasmatized due to the discharging, and a generated plasma gas is ejected. Since oxygen is contained as an active gas in the process gas, oxygen radicals are contained in the plasma gas. In a case where heat sinks 27 and 28 are not provided, the temperature of reaction chamber 38 rises due to application of a voltage to the electrodes 24 and 26 during plasmatization. However, in atmospheric-pressure plasma device 10, a cooling gas is supplied to the flow paths of heat sinks 27 and 28 by cooling gas supply device 102, and thus reaction chamber 38 is cooled through heat exchange. The cooling gas that flows through the flow paths of heat sinks 27 and 28 and is warmed through the heat exchange is supplied to gas pipe 110 to be heated by heater 112. The heated cooling gas is supplied to the inside of lower cover 22, and is ejected to the plasma gas from through-hole 70 of lower cover 22. through-hole 70 is located around nozzle block 36, and is disposed in the flow path of the plasma gas ejected from the lower end of nozzle block 36. The plasma gas is ejected along with the heated cooling gas from through-hole 70 of lower cover 22. The plasma gas is heated by the ejected heated cooling gas. Since heater 112 is controlled by control device 16, the temperature of the plasma gas is also controlled.

### EXAMPLES

In order to verify the effect of oil removal using atmospheric-pressure plasma gas irradiation in atmospheric-pressure plasma device 10, the following tests were conducted. First, four tabular test pieces that are aluminum die-cast components were prepared. The four test pieces were respectively coated with cutting oil for a machine tool at oil-level concentrations of 0%, 5%, 10%, and 15%. When the cutting oil is used in a machine tool, the oil-level concentration is 5 to 10%.

Here, the reason why the test pieces were aluminum die-cast components and cutting oil was used as removal target oil is that the use in the automobile manufacturing process is supposed. For example, a casing of an engine control unit (ECU) of an automobile is formed by multiple aluminum die-cast components, and cutting using cutting oil is performed. After the cutting, the cutting oil is removed, and then the components are bonded to each other by a bonding agent. The bonding agent here is the concept of having the adhesiveness and also including, for example, Formed IN Place Gaskets (FIPG) or a sealing agent having sealing property. Compositions of the cutting oil vary depending on manufacturers, but the cutting oil mainly contains paraffinic mineral oil and ester.

Next, the test pieces prior to plasma gas irradiation were analyzed using a Fourier transform infrared spectrophotometer (hereinafter referred to as FTIR). Next, the test pieces were irradiated with a plasma gas with a predetermined temperature by using atmospheric-pressure plasma device 10. Next, the test pieces after the plasma gas irradiation were analyzed using the FTIR.

FIGS. 4(a) to 4(d) illustrate results of analyzing the test pieces before and after plasma gas irradiation by using the FTIR. A solid line in each of FIGS. 4(a) to 4(d) indicates a spectrum before plasma gas irradiation, and a dashed line indicates a spectrum after plasma gas irradiation. FIGS. 4(a) to 4(d) respectively correspond to oil-level concentrations of 15%, 10%, 5% and 0%. The peak between 3000 and 2840 cm⁻¹ is derived from C—H stretching of an alkane. The peak between 1750 and 1735 cm⁻¹ is derived from C=O stretching of an ester. The peak between 1600 and 1400 cm⁻¹ is derived from C—H deformation of the alkane. The intensity of each peak increases as the oil-level concentration becomes higher. In each diagram of FIGS. 4(a) to 4(d), each peak of the spectrum after the plasma gas irradiation is reduced. This indicates that the cutting oil was decomposed due to the plasma gas irradiation.

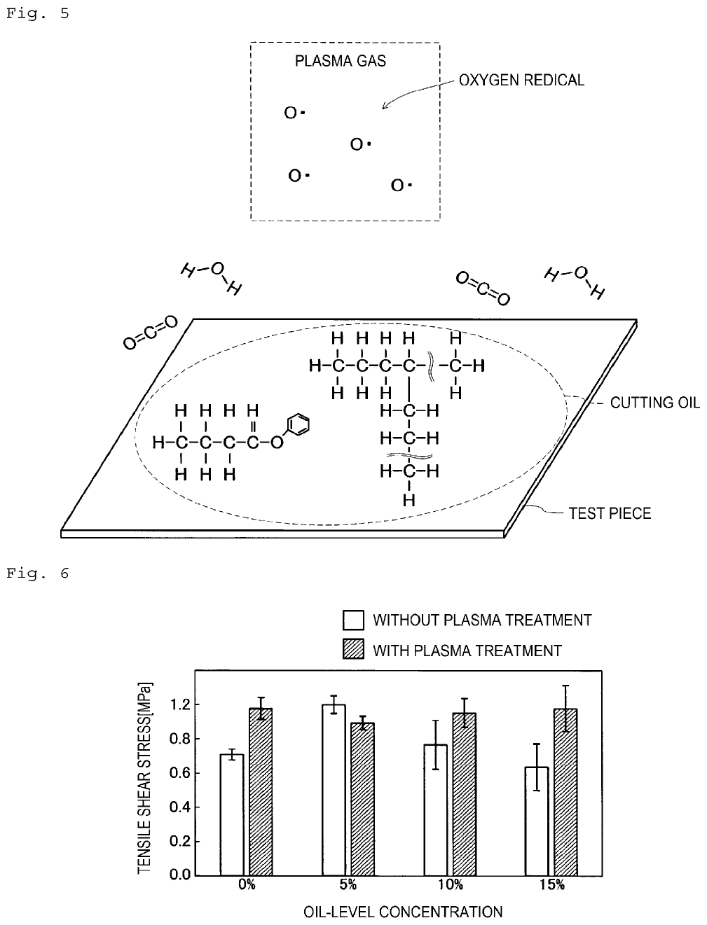

FIG. 5 is a diagram schematically illustrating a state of decomposition of the cutting oil due to plasma gas irradiation. The paraffinic mineral oil and ester contained in the cutting oil are decomposed by oxygen radicals contained in the plasma gas. Specifically, it is considered that, through reaction with the oxygen radicals, a carbon element contained in the cutting oil becomes carbon dioxide, and an oxygen element contained in the cutting oil becomes water.

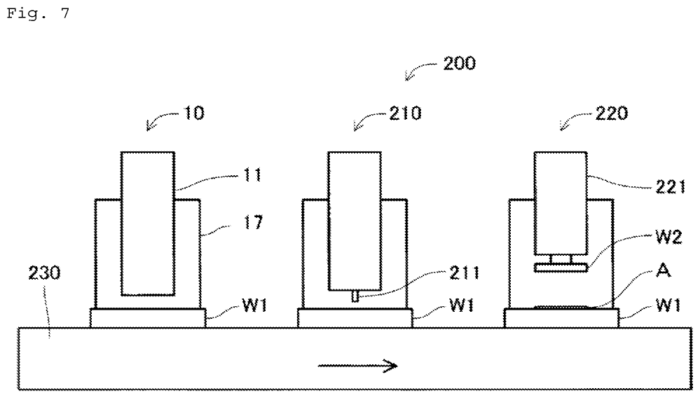

Next, a bonding agent was applied to the test piece after the plasma gas irradiation, and a tabular aluminum die-cast component that is an object to be bonded was bonded thereto. Specifically, the test piece and the object to be bonded were bonded to each other by interposing the bonding agent between a surface of the test piece irradiated with the plasma gas and the object to be bonded. As a comparative example, a cutting oil was applied to each of four test pieces that are aluminum die-cast components at oil-level concentrations of 0%, 5%, 10%, and 15%, and a bonding agent was interposed between coating surfaces and objects to be bonded without irradiation with a plasma gas, and the test pieces and the objects to be bonded were bonded to each other. The bonding agent is 1217M manufactured by Three Bond Holdings Co., Ltd., which is a one-pack cold-curing type silicone-based sealing agent for a FIPG of the deoxime type imparted with oily surface adhesiveness. Next, the bonded test piece and object to be bonded were pulled in directions parallel to the bonding surface and opposite to each other, and the maximum load at which the bonding surface was broken was measured. FIG. 6 illustrates measurement results (n=3) of the tensile shear stress obtained by dividing the maximum load by the area of the bonding surface. It can be seen that, at oil-level concentrations of 10% and 15%, the tensile shear stress of the test piece (with plasma treatment in FIG. 6) irradiated with a plasma gas is greater than that of the test piece (without plasma treatment in FIG. 6) not irradiated with the plasma gas. This is considered to be because the cutting oil that is a cause of the decrease in the bonding strength is decomposed due to the plasma gas irradiation. However, the bonding agent used is a bonding agent which is imparted with oily surface adhesiveness, that is, which achieves an effect of reducing the decrease in the bonding strength even though oil reducing the bonding strength is generally present on the bonding surface. Test results at the oil-level concentration of 5% are considered to reflect the characteristics of this bonding agent. Also at the oil-level concentration of 0%, a result is obtained in which the tensile shear stress of the test piece irradiated with the plasma gas is greater than the tensile shear stress of the test piece not irradiated with the plasma gas. This is considered to be because stains attached to the test piece were cleaned through irradiation with the plasma gas.

According to the embodiment described above, the following effects are achieved. Since a plasma gas can flow along a shape of a target object, the plasma gas can remove oil regardless of a shape of a portion of the target object to which the oil is attached. Since oxygen radicals are used, carbon elements and hydrogen elements constituting oil can be respectively decomposed into carbon dioxide and water to be removed. Therefore, paraffin and esters contained in the cutting oil can be decomposed. A bonding surface is irradiated with a plasma gas prior to bonding, and thus it is possible to decompose oil attached to the bonding surface and thus to improve the bonding strength.

### Second Embodiment

### (Assembly Device)

Next, assembly device 200 in which plasma gas irradiation, bonding agent application, and mounting of an object to be bonded are performed in series will be described with reference to FIG. 7. Assembly device 200 includes atmospheric-pressure plasma device 10, coating device 210, mounting device 220, and moving device 230. Atmospheric-pressure plasma device 10 includes plasma head 11, control device 16, process gas supply device 77, and main body portion 17 storing cooling gas supply device 102. Moving device 230 is, for example, a belt conveyor, and moves workpiece W1 placed on an upper surface thereof to each work position to atmospheric-pressure plasma device 10, coating device 210, and mounting device 220 in this order. Workpiece W1 is made of a resin, and oil is attached to a surface thereof. Coating device 210 ejects and applies bonding agent A to a bonding surface of workpiece W1 from ejecting nozzle 211. Mounting device 220 mounts object W2 to be bonded that is picked up by suction head 221 onto the bonding surface coated with bonding agent A. In other words, mounting device 220 bonds workpiece W1 to object W2 to be bonded by interposing the bonding agent between a portion of the workpiece W1 from which oil has been removed through plasma irradiation from atmospheric-pressure plasma device 10 and object W2 to be bonded. The temperature of the plasma gas applied from atmospheric-pressure plasma device 10 is controlled by control device 16 to a temperature lower than a melting point of workpiece W1 made of a resin.

In the above embodiment, plasma head 11 is an example of an irradiation section, control device 16 is an example of a control section, and coating device 210 and mounting device 220 are an example of a bonding section. Electrodes 24 and 26 are an example of a pair of electrodes. Heat sinks 27 and 28 are an example of a cooler, and heater 112 is an example of a heating device. The cooling gas is an example of a cooling-heating gas, connecting block 114 and lower cover 22 are an example of a connecting section, and through-hole 70 is an example of an ejection port.

According to the embodiment described above, the following effects are achieved. Since a plasma gas applied from atmospheric-pressure plasma device 10 is controlled to a temperature lower than a melting point of workpiece W1 made of a resin, oil can be removed while reducing damage to workpiece W1. Since assembly device 200 includes atmospheric-pressure plasma device 10, coating device 210, and mounting device 220, plasma gas irradiation work, bonding agent coating work, and mounting work for object W2 to be bonded can be performed as assembly line work.

Needless to say, the present disclosure is not limited to the above embodiments, and various modifications and changes may occur without departing from the spirit of the present disclosure. For example, the above-described configuration has been illustrated in which assembly device 200 performs each piece of work on tabular workpiece W1, however, the configuration is not limited to this. For example, each of plasma head 11, ejecting nozzle 211, and suction head 221 may be provided in an articulated robot, and positions of plasma head 11, ejecting nozzle 211, and suction head 221 may be adjusted with respect to a workpiece having a curved surface at an angle corresponding to the curved surface. A workpiece may be moved by a belt conveyor or the like to each work position, and articulated robots may be moved to a workpiece of which a position is fixed, so that each piece of work is performed on the workpiece.

A target to which the above technique is applied is not limited to an aluminum die-cast ECU case. For example, the above technique may be applied to oil removal of, for example, an oil van of an automobile made of aluminum or resin. Oxygen plasma may be applied to cleaning of a stain containing a carbon element, attached to a metal component of, for example, an automobile before welding by using a principle of generating carbon dioxide through bonding to the carbon element.

In the above description, lower housing 20 has been described as having earth plate 32 but is not limited to this, and the configuration without having earth plate 32 may be also adopted.

### REFERENCE SIGNS LIST

10 Atmospheric-pressure Plasma Device, 11 Plasma Head, 16 Control device, 22 Lower Cover, 24, 26 Electrode, 27, 28 Heat Sink, 36 Nozzle Block, 38 Reaction Chamber, 200 Assembly Device, 210 Coating Device, 220 Mounting Device, 110 Gas Pipe, 112 Heater, 114 Connecting Block

1. An oil removal method comprising a step of irradiating oil attached to a target object with a plasma gas that has been plasmatized by atmospheric-pressure plasma.

2. The oil removal method according to claim 1, wherein the plasma gas contains oxygen plasma.

3. The oil removal method according to claim 1, further comprising a step of controlling a temperature of the plasma gas.

4. The oil removal method according to claim 1, wherein the target object is a metal and the oil is cutting oil.

5. The oil removal method according to claim 3, wherein the target object is a resin, and the temperature of the plasma gas is controlled to a temperature lower than a melting point of the resin.

6. A bonding method comprising:
an oil removal step of removing the oil attached to the target object by using the oil removal method according to claim 1; and
a bonding step of bonding the target object to an object to be bonded by interposing a bonding agent between a portion of the target object from which the oil has been removed and the object to be bonded.

7. An assembly device comprising:
an irradiation section configured to irradiate oil attached to a target object made of a resin with a plasma gas containing oxygen plasma that has been plasmatized by atmospheric-pressure plasma;
a control section configured to control a temperature of the plasma gas to a temperature lower than a melting point of the target object; and
a bonding section configured to bond the target object to an object to be bonded by interposing a bonding agent between a portion of the target object from which the oil has been removed and the object to be bonded.

8. An atmospheric-pressure plasma device comprising:
an irradiation section configured to irradiate oil attached to a target object made of a resin with a plasma gas containing oxygen plasma that has been plasmatized by atmospheric-pressure plasma; and
a control section configured to control a temperature of the plasma gas to be a temperature lower than a melting point of the target object,
wherein the irradiation section has:
a pair of electrodes configured to generate plasma through discharge,
a reaction chamber that incorporates the pair of electrodes and includes an outlet through which the plasma gas plasmatized by the pair of electrodes flows out,
a nozzle block that communicates with the reaction chamber, the nozzle block being configured to eject the plasma gas,
a cooler that has a gas flow path through which a cooling-heating gas flows, the cooler being configured to cool the reaction chamber, and
a gas pipe that is connected to the gas flow path and through which the cooling-heating gas flows,
a heating device that is disposed at the gas pipe, and
a connecting section that is connected to the gas pipe and has an ejection port in a flow path for the plasma gas,
wherein the cooling-heating gas heated by the heating device is ejected to the plasma gas from the ejection port so that the plasma gas is heated, and
wherein the control section controls a temperature of the plasma gas by controlling the heating device.
